(19) United States
(12) Patent Application Publication
(10) Pub. No.: US 2003/0219953 A1
(43) Pub. Date: Nov. 27, 2003

(54) Method for fabricating semiconductor devices

(75) Inventor: Satoru Mayuzumi, Kanagawa (JP)

Correspondence Address: SUGHRUE MION, PLLC, 2100 PENNSYLVANIA AVENUE, N.W., WASHINGTON, DC, 20037, US

(73) Assignee: NEC ELECTRONICS CORPORATION

(21) Appl. No.: 10/441,178

(22) Filed: May 20, 2003

(30) Foreign Application Priority Data
May 23, 2002 (JP) 148808/2002

(51) Int. Cl. H01L 21/331

(52) U.S. Cl. 438/353

(57) ABSTRACT

A method for fabricating semiconductor devices, disclosed herein, comprises the steps: covering a semiconductor substrate on which there are an area of forming a first MOSFET and an area of forming a second MOSFET with an insulation layer only in the area of forming the second MOSFET; forming a first trench in which a gate electrode will be formed in the area of forming the first MOSFET, using the insulation layer as a mask; forming a first gate insulation layer on the bottom of the first trench; forming a first gate electrode by filling the first trench with a conductive layer; covering the area of forming the first MOSFET with an insulation layer; forming a second trench in which a gate electrode will be formed in the area of forming the second MOSFET; forming a second gate insulation layer whose thickness is different from the thickness of the first gate insulation layer on the bottom of the second trench; and forming a second gate electrode by filling the second trench with a conductive layer.

### BACKGROUND OF THE INVENTION

1. Field of the Invention

The present invention relates to a method for fabricating semiconductor devices and, more particularly, to a method for fabricating MOSFETs especially fit for SOC (System On a Chip), using a damascene process.

2. Description of the Prior Art

MOSFETs fabrication technology using the damascene process to form gate electrodes has heretofore been known. This technology has been disclosed in, for example, Japanese Unexamined Patent Application Publication No. Hei 8-37296 (No. 37296 of 1996). FIGS. 12A through 12C, 13A, and 13B are cross-sectional diagrams illustrating the sequential steps of fabricating a MOSFET by the MOSFET fabrication method of prior art disclosed in the above Publication.

First, as is shown in FIG. 12A, an insulation layer 65 containing n-type impurities is formed on a p-type silicon (Si) substrate 1. For the insulation layer 65, for example, a phosphor-silicate glass (PSG) film deposited up to a thickness of about 400 nm by low pressure-chemical vapor deposition (LP-CVD) is used.

Next, a resist pattern 13 for forming a gate electrode is formed on the insulation layer 65. Using the resist pattern 13 as a mask, the insulation layer 65 is anisotropically etched and removed through a reactivity ion etching (RIE) process, and an opening 14 is formed.

Then, as is shown in FIG. 12B, a PSG layer 66 approximately 100 nm thick is deposited over the entire area over the silicon substrate 1 through the LP-CVD process. At this time, the phosphor (P) concentration in the PSG layer 106 is made lower than that in the insulation layer 65.

Next, as is shown in FIG. 12C, the formed PSG layer 66 portions at the bottom of the opening 14 and covering the insulation layer 65 are removed by etching back the PSG layer 66, so that PSG layers for spacers 66a are formed on the side walls of the opening 14.

Then, a gate insulation layer 15 is formed on the surface of the p-type Si substrate 1 in the bottom of the opening 14 by a thermal oxidation process. Next, from the insulation layer 65 and the PSG layers for spacers 66a, P is diffused into the Si substrate 1 through a thermomigration process so that source/drain regions are formed. The source/drain regions each consist of an n+ layer 11 and an n− layer 10. The n+ layer 11 is formed by P diffusion from the insulation layer 65 adjacent thereto and the n− layer 10 is formed by P diffusion from the PSG layer 66a for spacer adjacent thereto.

Next, a conductive layer 16, approximately 600 nm thick, made of a low resistance material such as tungsten (W), is deposited over the entire area over the Si substrate 1. Then, as is shown in FIG. 13B, the conductive layer 16, insulation layer 65, PSG layers 66a for spacers are polished by chemical mechanical polishing (CMP), so that they are partially removed and a planar top surface is created. In consequence, a damascene gate electrode 16a made of W is formed. In the manner described above, a MOSFET is fabricated.

FIGS. 14A through 14D are cross-sectional diagrams illustrating the sequential steps of fabricating a MOSFET by the MOSFET fabrication method of prior art disclosed in the above Publication.

First, as is shown in FIG. 14A, after device isolation regions 72 are formed on the surface of a p-type Si substrate 71, a silicon oxide layer and a polycrystalline silicon layer are deposited over the entire area over the Si substrate 71. Then, a dummy gate insulation layer 75a and a dummy gate electrode 76a are formed by patterning the silicon oxide layer and polycrystalline silicon layer. Next, after side walls 79 made of a silicon nitride film are formed on the sides of the dummy gate electrode 76a, impurity diffusion layers 80, 81 that act as source and drain regions are formed by implanting impurity ions into these layers, using the dummy gate electrode 76a and side walls 79 as masks, followed by a heating process for activating the impurity ions. Then, silicide regions 82 are formed on top of the dummy gate electrode 76a and the impurity diffusion layers 81 by depositing metal containing titanium (Ti) and cobalt (Co), which has a high melting point, on the Si substrate 71, followed by a heating process. Next, after interlayer dielectric layers 95 made of a silicon oxide film are deposited on all surfaces of the dummy gate electrode 76a, the interlayer dielectric layers 95 are planarized through the CMP process to expose the dummy gate electrode 76a.

Next, as is shown in FIG. 14B, only the dummy gate electrode 76a and dummy gate insulation layer 75a are removed to form a trench 84 in which a gate electrode will be embedded.

Next, as is shown in FIG. 14C, a tantalum oxide layer (Ta₂O₅) 85 and a metal layer 86 made of tungsten nitride (TiW) or tungsten (W) are sequentially deposited on the bottom and inside walls of the trench 84 and on the interlayer dielectric layers 95.

Then, as is shown in FIG. 14D, the exposed portions of the Ta₂O₅ layer 85 and metal layer 86 on the interlayer dielectric layers 95 are removed through the CMP process to form a gate insulation layer 85 consisting of the remaining Ta₂O₅ layer 85 and a gate electrode 86a consisting of the remaining metal layer 86. A MOSFET is thus fabricated.

In the above-discussed two MOSFET fabrication methods of prior art, over the entire area of forming the gate electrode on the p-type silicon substrate, the trench is formed in which the gate electrode should be embedded. Thereafter, the gate insulation layer and the metal layer for embedding the gate electrode are sequentially deposited over the entire area over the p-type silicon substrate and the gate electrode is formed by performing the CMP. Accordingly, all gate electrodes to be formed on the p-type silicon substrate are formed at a time and all the gate electrodes thus formed are made of same material and equal in thickness, and so are their gate insulation layers.

For this reason, it is difficult to form MOSFETs with their gate insulation layers differing in thickness on a same substrate, using the prior art method of semiconductor device fabrication using the damascene gate process. Also, it is impossible to form MOSFETs with their gate electrodes made of different materials and gate insulation layers made of different materials on a same substrate. It is therefore difficult to form MOSFETs with different supply voltages and thresholds on a same substrate and it is difficult to use a higher threshold voltage to reduce leakage current when forming complementary MOSFETs (CMOSFETs) having metal gates. In the following, these problems will be further discussed.

In current semiconductor fabrication equipment technology, two types of MOSFETs can be produced: MOSFETs with a high threshold, intended to decrease leakage current during a standby; and MOSFETs with a low threshold, intended to increase their operating speed. The gate insulation layers of each type differ in thickness. For MOSFETs designed to operate on different supply voltages, their gate insulation layers differ in thickness. Thus, in order to co-fabricate these types of MOSFETs on a same chip, gate insulation layers with different thicknesses must be formed on the same silicon substrate.

Another problem with conventional MOSFETs is that thinner silicon oxide gate insulation layers are liable to cause a tunnel current in the gate electrode and this results in increase in leakage current. To suppress this problem, approaches to increasing the effective gate insulation layer thickness through the use of high permittivity materials such as Ta₂O₅ to make gate insulation layers have been studied. When co-fabricating several MOSFETs on a same chip such as is the case in the SOC, it would be required to form MOSFETs with gate insulation layers made of a conventional silicon oxide film and MOSFETs with gate insulation layers made of a high permittivity material on the same silicon substrate. However, the prior art fabrication technology would form uniform gate insulation layers of all MOSFETs to be formed on the silicon substrate at a time. With this technology, it is difficult to co-fabricate MOSFETs using gate insulation layers that differ in thickness and type on a same chip.

Meanwhile, in complementary MOSFETs (CMOSFETs) having polysilicon gates which have been used conventionally, n-type impurities are doped into an n-type MOSFET gate electrode and p-type impurities are doped into a p-type MOSFET gate electrode. Thereby, the work function of each gate electrode is reduced and the thresholds of the n-type and p-type MOSFETs are lowered. However, because n-type and p-type impurities cannot be doped into metal gates, if metal gates are formed by the prior art fabrication technology, gate electrodes of same material are formed in both n-type and p-type MOSFETs. Therefore, it is difficult to maintain high performance of the CMOSFETs while lowering their threshold voltages.

### BRIEF SUMMARY OF THE INVENTION

Summary of the Invention

The present invention provides a method for fabricating semiconductor devices, comprising the steps: covering a semiconductor substrate on which there are an area of forming a first MOSFET and an area of forming a second MOSFET with an insulation layer only in the area of forming the second MOSFET; forming a first trench in which a gate electrode will be formed in the area of forming the first MOSFET, using the insulation layer as a mask; forming a first gate insulation layer on the bottom of the first trench; forming a first gate electrode by filling the first trench with a conductive layer; covering the area of forming the first MOSFET with an insulation layer; forming a second trench in which a gate electrode will be formed in the area of forming the second MOSFET; forming a second gate insulation layer whose thickness is different from the thickness of the first gate insulation layer on the bottom of the second trench; and forming a second gate electrode by filling the second trench with a conductive layer.

### BRIEF DESCRIPTION OF THE DRAWINGS

The above-mentioned and other objects, features and advantages of this invention will become more apparent by reference to the following detailed description of the invention taken in conjunction with the accompanying drawings, wherein:

FIG. 1 is a schematic cross-sectional diagram of a MOSFETs structure in accordance with a preferred Embodiment 1 of the present invention.

FIGS. 2A-2D are schematic cross-sectional diagrams illustrating a first method for fabricating MOSFETs in accordance with Embodiment 1 of the invention.

FIGS. 3A-3D are schematic cross-sectional diagrams illustrating the fabrication method following the phase of FIG. 2.

FIGS. 4A-4D are schematic cross-sectional diagrams illustrating the fabrication method following the phase of FIG. 3.

FIGS. 5A-5E are schematic cross-sectional diagrams illustrating a second method for fabricating MOSFETs in accordance with Embodiment 1 of the invention.

FIGS. 6A-6E are schematic cross-sectional diagrams illustrating the fabrication method following the phase of FIG. 5.

FIG. 7 is a schematic cross-sectional diagram of a MOSFETs structure in accordance with a preferred Embodiment 2 of the present invention.

FIGS. 8A-8D are schematic cross-sectional diagrams illustrating a method for fabricating MOSFETs in accordance with Embodiment 2 of the invention.

FIGS. 9A-9D are schematic cross-sectional diagrams illustrating the fabrication method following the phase of FIG. 8.

FIGS. 10A-10C are schematic cross-sectional diagrams illustrating the fabrication method following the phase of FIG. 9.

FIGS. 11A-11C are schematic cross-sectional diagrams illustrating the fabrication method following the phase of FIG. 10.

FIGS. 12A-12C are schematic cross-sectional diagrams illustrating a first process of semiconductor device fabrication of prior art

FIGS. 13A and 13B are schematic cross-sectional diagrams illustrating the fabrication process following the phase of FIG. 12.

FIGS. 14A-14D are schematic cross-sectional diagrams illustrating a second process of semiconductor device fabrication of prior art.

### DETAILED DESCRIPTION OF THE INVENTION

The present invention now is described more fully hereinafter with reference to the accompanying drawings, in which preferred embodiments of the invention are shown. First, a preferred Embodiment 1 of the present invention will be described.

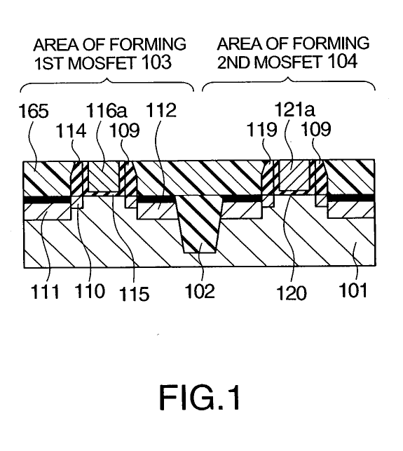

FIG. 1 is a cross-sectional diagram of a MOSFETs structure in accordance with Embodiment 1. As is shown in FIG. 1, in the MOSFETs structure of Embodiment 1, a device isolation layer 102 is created on the surface of a p-type silicon (Si) substrate 101. The device isolation layer 102 is formed by shallow trench isolation (STI), made of a plasma oxide film or the like. The device isolation layer 102 forms the boundary between the areas of forming devices on the surface of the Si substrate 101 and, in the present embodiment, it forms the boundary between the area of forming a first MOSFET 103 and the area of forming a second MOSFET 104. An insulation layer 165 covers the Si substrate 101 and a trench 114 in which a gate electrode will be formed is created in the area of forming the first MOSFET 103. Inside the trench 114 in which a gate electrode will be formed, a gate insulation layer 115 and a gate electrode 116a are formed. The gate insulation layer 115 is made of material such as SiO₂, SiON, ZrO₂, HfO₂, Ta₂O₅, Al₂O₃, TiO₂, etc. The conductive layer that constitutes the gate electrode 116a is made of material such as AL, Mo, TaN, W, Ti, Ni, Co, V, Zr, and SiGe. Although the gate electrode 116a consists of a single conductive layer in this embodiment example, it may consist of two ore more conductive layers, wherein the conductive layers are arranged so that one of the conductive layers of the gate electrode 116a contacts the gate insulation layer 115. Similarly, a trench 119 in which a gate electrode will be formed is created in the area of forming the second MOSFET 104. Inside the trench 119, a gate insulation layer 120 and a gate electrode 121a are formed. The gate insulation layer 120 may be made of a different material than or the same material as the material of the gate insulation layer 115 formed in the area of the first MOSFET. Also, the thickness of the gate insulation layer 120 may differ from that of the gate insulation layer 115. Moreover, the gate electrode 121a also may be made of a different material than the material of the gate electrode 116a formed in the area of the first MOSFET. According to the transistor type to be formed on the Si substrate 101, the materials of the gate electrodes and the gate insulation layers to be formed in the area of forming the first MOSFET 103 and the area of forming the second MOSFET 104 can thus be selected. Furthermore, side walls 109 are formed on the sides of the first gate electrode 116a and the second gate electrode 121a. The side walls 109 are formed by depositing a single layer or a plurality of layers of an insulating material such as, for example, SiO₂ or Si₃N₄. Moreover, extension regions 110 are created from under the side walls 109 to the device isolation region 102 on the surface of the Si substrate 101. Also, diffusion layer regions 111 are created from the ends of the sidewalls 109 to the device isolation region 102 on the surface of the Si substrate 101. Impurities are implanted into the extension regions 110 and the diffusion layer regions 111 and the extension regions 110 are shallower than the diffusion layer regions 111 in junction depth. The extension regions 110 and diffusion layer regions 111 form source/drain regions on the either sides of the first gate electrode 116a and the second gate electrode 121a. Some of the diffusion layer regions 111 are overlaid with suicides 112 that have been formed through the reaction of the Si substrate 101 with a metal having a high melting point such as Ti, Co, or Ni. In the present embodiment, it is possible to form CMOSFETs in which it is required to make gate electrodes of different materials with different work functions; two types of MOSFETs with different thresholds or “off” leakage currents; and two types of MOSFETs with different supply voltages.

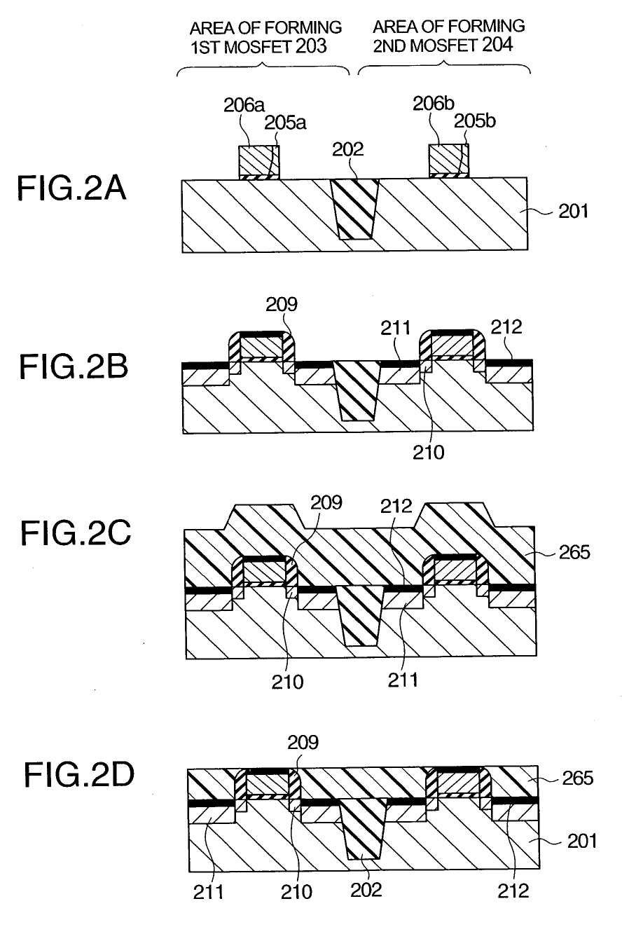

Then, a method for fabricating MOSFETs in accordance with Embodiment 1 will be explained. FIGS. 2A through 2D, FIGS. 3A through 3D, and FIGS. 4A through 4D are cross-sectional diagrams illustrating the sequential steps of fabricating MOSFETs by the above method. First, as is shown in FIG. 2A, a device isolation layer 202 is formed on the surface of a p-type Si substrate 201 to form the boundary between the area of forming a first MOSFET 203 and the area of forming a second MOSFET 204. In this case, the device isolation layer 202 is formed by STI, made of a plasma oxide film or the like. Then, well implantation is performed in the area of forming the first MOSFET 203 and the area of forming the second MOSFET 204.

Next, after a gate insulation layer that is approximately 3 nm thick and a polycrystalline silicon (Si) layer that is approximately 150 nm thick are grown, the gate insulation layer and the polycrystalline Si layer are patterned. The gate insulation layer may be made of material such as SiO₂, SiON, ZrO₂, HfO₂, Ta₂O₅, Al₂O₃, TiO₂, etc. By patterning the above layers, a first dummy gate insulation layer 205a and a first dummy gate electrode 206a are formed in the area of forming the first MOSFET 203 and a second dummy gate insulation layer 205b and a second dummy gate electrode 206b are formed in the area of forming the second MOSFET 204.

Next, as is shown in FIG. 2B, using the first and second dummy gate electrodes 206a, 206b as masks, impurities are implanted into the Si substrate 201. If the MOSFET to be formed is an NMOS, n-type impurities such as As must be implanted; if it is a PMOS, p-type impurities such as B must be implanted. Ion implantation of impurities is performed with energy of about 5 keV at an angle of 30 degrees obliquely to the Si substrate 201. If both NMOS and PMOS types are formed on the Si substrate 201, first, mask the area of forming the NMOS with resist and implant B into only the PMOS area. Then, mask the area of forming the PMOS with resist and implant As into only the NMOS area. The order in which these impurities are implanted may be reversed. In consequence, extension regions 210 are formed. Thereafter, pocket implantation may be performed, if necessary, to prevent punch-through.

Next, after an insulation layer approximately 700 nm thick is deposited over the entire area over the Si substrate 201, the insulation layer is anisotropically etched to form side walls 209. Insulation layers that form the side walls 209 are formed by depositing a single layer or a plurality of layers of an insulating material such as SiO₂ or Si₃N₄.

Then, using the dummy gate electrodes 206a, 206b and the side walls 209 as masks, impurities are implanted into the Si substrate 201. If an NMOS is formed, implant n-type impurities such as As with energy of about 3 keV. If a PMOS is formed, implant p-type impurities such as B with energy of about 3 keV. Ion implantation of impurities is performed at a right angle to the Si substrate 201. If both NMOS and PMOS types are formed on the Si substrate 201, alternately select the area to be ion implanted with impurities and mask the deselected area with resist as is the case when forming the extension regions 210. Thereafter, annealing is performed to form diffusion layer regions 211 that behave as source or drain regions.

Next, a metal having a high melting point such as Ti, Co, or Ni is deposited over the entire area over the Si substrate 201 to make an approximately 20 nm thick metal layer and a heating process is applied, thereby forming silicides 212 on the diffusion layer regions 211 and on the dummy gate electrodes 206a, 206b.

Next, as is shown in FIG. 2C, an interlayer dielectric layer 265, approximately 800 nm thick, made of SiO² or the like, is deposited over the entire area over the Si substrate 201 through the CVD process. The thus deposited dielectric layer may be a lamination consisting of the layers of Si₃N₄ and SiO₂, and the like.

Then, as is shown in FIG. 2D, the interlayer dielectric layer 265 is planarized and removed through the CMP process until the top surfaces of the first and second dummy gate electrodes 206a, 206b are exposed.

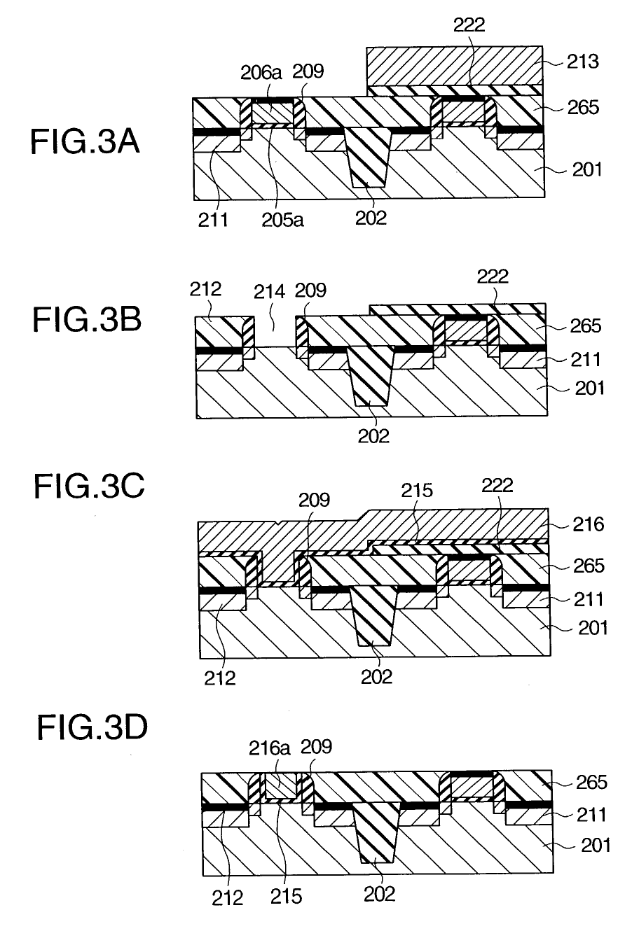

Next, as is shown in FIG. 3A, a first insulation layer 222, approximately 20 nm thick, made of a nitride film or the like, is deposited over the entire area over the Si substrate 201 through the CVD process. Then, a resist pattern 213 is formed to cover the area of forming the second MOSFET and, using the resist pattern 213 as a mask, the first insulation layer 222 is wet etched with phosphoric acid or the like.

Next, as is shown in FIG. 3B, after the resist 213 is removed, wet etching is performed, using an alkaline solution such as KOH, and thereby, the first dummy gate electrode 206a is removed. Then, the first dummy gate insulation layer 205a is removed, using hydrofluoric acid or the like, and, inconsequence, a first trench 214 is formed in which a gate electrode will be formed.

Next, as is shown in FIG. 3C, a first gate insulation layer 215 approximately 3 nm thick is formed inside the first trench 214. When material such as ZrO₂, HfO₂, Ta₂O₅, Al₂O₃, or TiO₂ is deposited through the CVD process to form the first gate insulation layer 215, the material is deposited not only inside the first trench 214, but also on the interlayer dielectric layer 265 and the first insulation layer 222. Alternatively, when SiO₂, SiON, or the like is grown through a thermal oxidation process, the first gate insulation layer 215 is formed only on the bottom of the first trench 214. Thereafter, a first conductive layer 216 is deposited over the entire area through a sputter or CVD process. The first conductive layer 216 is formed, consisting of a single layer or a plurality of layers of AL, Mo, TaN, W, Ti, Ni, Co, V, Zr, and SiGe.

Next, as is shown in FIG. 3D, the first conductive layer 216 and the first insulation layer 222 over the interlayer dielectric layer 265 are removed through the CMP process, a first gate electrode 216a is formed, and the top surface of the second dummy gate electrode 206b is exposed.

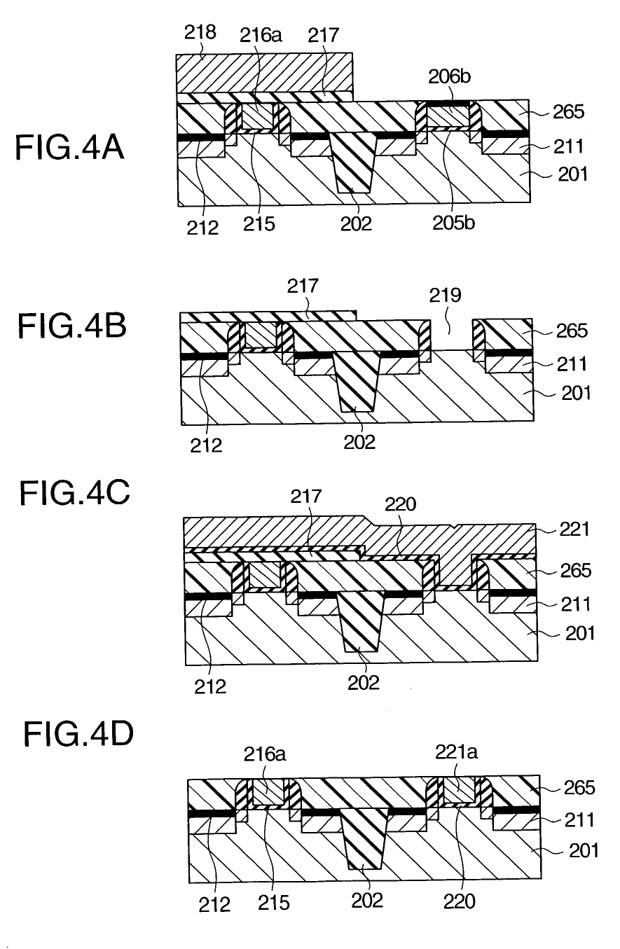

Next, as is shown in FIG. 4A, a second insulation layer 217, approximately 20 nm thick, made of a nitride film or the like, is deposited over the entire area over the Si substrate 201 through the CVD method. Then, a resist 218 is patterned to cover the area of forming the first MOSFET and, using the resist 218 as a mask, the second insulation layer 217 is wet etched with phosphoric acid or the like.

Next, as is shown in FIG. 4B, after the resist 218 is removed, wet etching is performed, using an alkaline solution such as KOH, and thereby, the second dummy gate electrode 206b is removed. Then, the second dummy gate insulation layer 205b is removed, using hydrofluoric acid or the like, and, inconsequence, a second trench 219 is formed in which a gate electrode will be formed.

Next, as is shown in FIG. 4C, a second gate insulation layer 220 is formed inside the second trench 219. Although the second gate insulation layer 220 is formed in the same way as for the first gate insulation layer 215, its material and thickness may be the same as or different from those of the first gate insulation layer. Material and thickness can be changed to the optimum for the MOSFET to be formed. In this case, the second gate insulation layer, for example, approximately 1.5 nm thick, is formed. Thereafter, a second conductive layer 221 is deposited over the entire area through the sputter or CVD process. Although the second conductive layer 221 is formed in the same way as for the first conductive layer 216, its material may be the same as or different from that of the first conductive layer. As is the case for the gate insulation layers, the material can be changed to the optimum for the MOSFET to be formed.

Next, as is shown in FIG. 4D, the second conductive layer 221 and the second insulation layer 217 over the interlayer dielectric layer 265 are removed through the CMP process, a second gate electrode 221a is formed, and the top surface of the first gate electrode 216a is exposed. In the manner described above, MOSFETs having different gate electrodes or gate insulation layers can be formed in the areas of forming the first and second MOSFETs 203, 204.

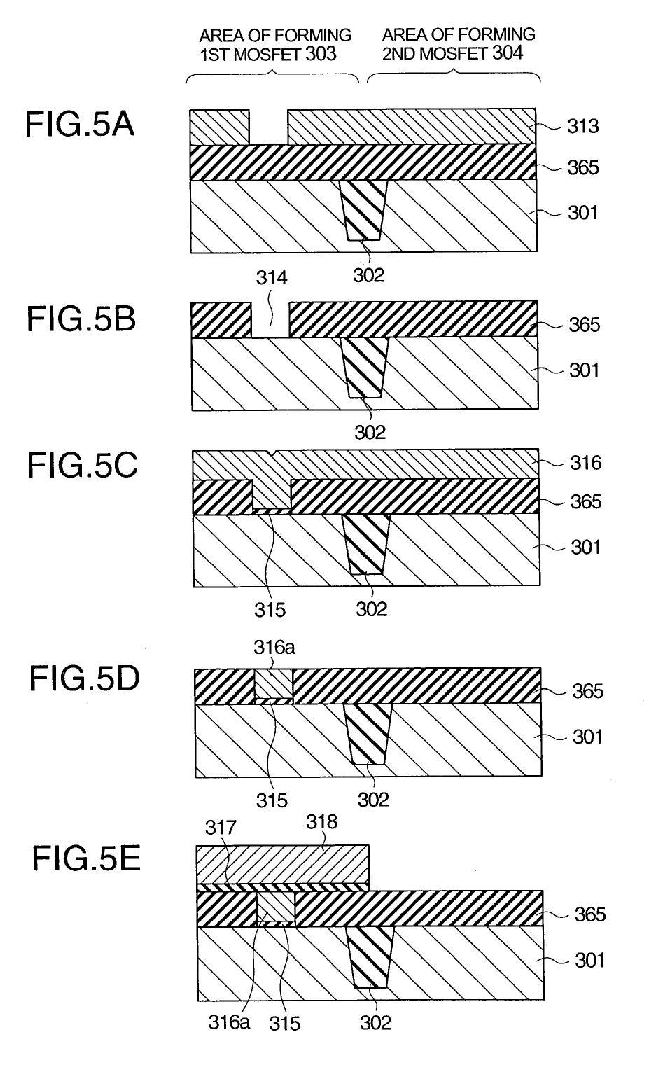

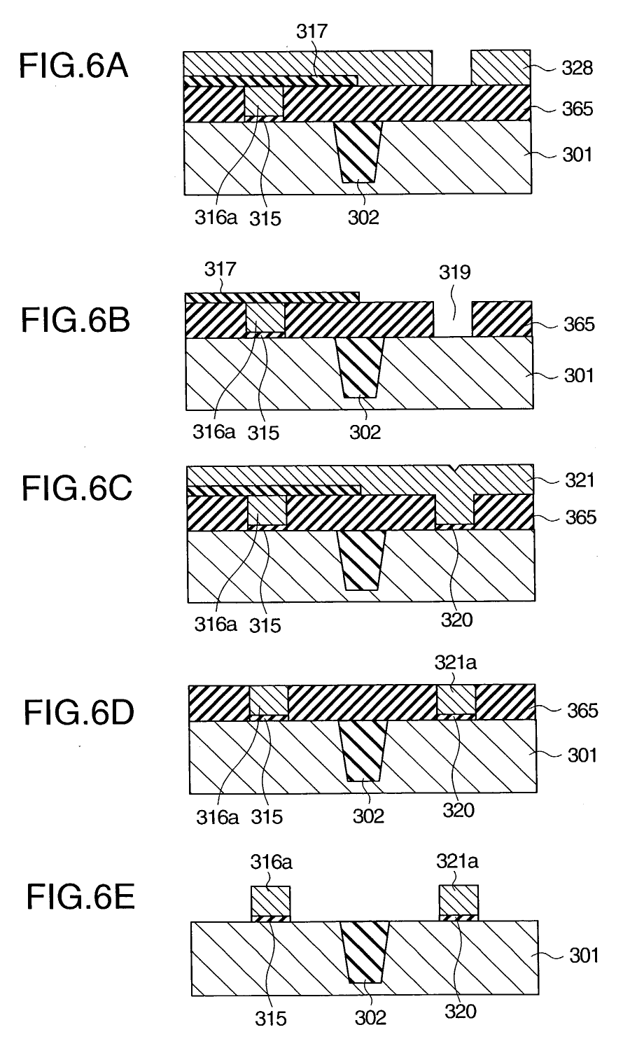

In the following, a second method for fabricating MOSFETs will be explained, which is different from the method for fabricating MOSFETs of Embodiment 1, by which the basic MOSFETs structure shown in FIG. 1 is created. FIGS. 5A through 5E and FIGS. 6A through 6E are cross-sectional diagrams illustrating the sequential steps of fabricating MOSFETs by the second method in accordance with the present embodiment.

First, as is shown in FIG. 5A, a device isolation layer 302 is formed on the surface of a p-type Si substrate 301 to form the boundary between the area of forming a first MOSFET 303 and the area of forming a second MOSFET 304. In this case, the device isolation layer 302 is formed by STI, made of a plasma oxide film or the like. Then, well implantation is performed in the area of forming the first MOSFET 303 and the area of forming the second MOSFET 304. Thereafter, an interlayer dielectric layer 365, approximately 200 nm thick, made of SiO₂, is deposited over the entire surface of the Si substrate 301

Then, a resist pattern 313 is formed in the area of forming the first MOSFET 303, which is used to form a trench in which a gate electrode will be formed (FIG. 5A).

Next, as is shown in FIG. 5B, using the resist pattern 313 as a mask, the interlayer dielectric layer 365 is anisotropically etched, and thereby, the Si substrate 301 is exposed and a first trench 314 is formed in which a gate electrode will be formed.

Next, as is shown in FIG. 5C, a first gate insulation layer 315 is formed inside the first trench 314. To form the first gate insulation layer 315, for example, SiO₂, SiON, or the like is grown through a thermal oxidation process. Then, the first gate insulation layer 315 is formed only on the bottom of the first trench 314. Alternatively, the first gate insulation layer 315 may be formed by depositing material such as ZrO₂, HfO₂, Ta₂O₅, Al₂O₃, or TiO₂ through the CVD process, wherein the material is deposited not only inside the first trench 314, but also over the entire surface of the interlayer dielectric layer 365. In this case, the first gate insulation layer 315, for example, approximately 3 nm thick, is formed. Thereafter, a first conductive layer 316 is deposited over the entire area through the sputter or CVD process. The first conductive layer 316 is formed, consisting of a single layer or a plurality of layers of AL, Mo, TaN, W, Ti, Ni, Co, V, Zr, and SiGe.

Next, as is shown in FIG. 5D, the first conductive layer 316 over the interlayer dielectric layer 365 is removed through the CMP process and a first gate electrode 316a is formed.

Then, an insulation layer 317, approximately 20 nm thick, made of Si3N4 or the like, is deposited over the entire surface of the interlayer dielectric layer 365 through the CVD method. Thereafter, a resist 318 is patterned to cover the area of forming the first MOSFET 303. Using the resist 318 as a mask, the insulation layer 317 is wet etched with phosphoric acid or the like to expose the interlayer dielectric layer 365 in the area of forming the second MOSFET 304.

Next, as is shown in FIG. 6A, after the resist 318 is removed, a resist pattern 328 is formed in the area of forming the second MOSFET 304, which is used to form a trench in which a gate electrode will be formed.

Next, as is shown in FIG. 6B, using the resist pattern 328 as a mask, the interlayer dielectric layer 365 is anisotropically etched, and thereby, the Si substrate 301 is exposed and a second trench 319 is formed in which a gate electrode will be formed.

Then, as is shown in FIG. 6C, a second gate insulation layer 320 is formed inside the second trench 319. Although the second gate insulation layer 320 is formed in the same way as for the first gate insulation layer 315, its material and thickness maybe different from or the same as those of the first gate insulation layer. Material and thickness optimum for the MOSFET to be formed can be selected. In this case, the second gate insulation layer, for example, approximately 1.5 nm thick, is formed. Thereafter, a second conductive layer 321 is deposited over the entire area through the sputter or CVD process. Although the second conductive layer 321 is formed in the same way as for the first conductive layer 316, its material may be the same as or different from that of the first conductive layer. Material can be changed to the optimum for the MOSFET to be formed.

Next, as is shown in FIG. 6D, the second conductive layer 321 and the insulation layer 317 over the interlayer dielectric layer 365 are removed through the CMP process, a second gate electrode 321a is formed, and the top surface of the first gate electrode 316a is exposed.

Next, as is shown in FIG. 6E, the interlayer dielectric layer 365 is removed by being anisotropically etched or wet etched with hydrofluoric acid. In the manner described above, metal gate electrodes can be formed in the areas of forming the first and second MOSEFTs 303, 304.

After that, the gate electrodes or MOSEFTs with their gate insulation layers made of different materials can be formed in the areas of forming the first and second MOSEFTs 303, 304 by forming the diffusion layer regions in the same way as that for forming normal MOSEFTs.

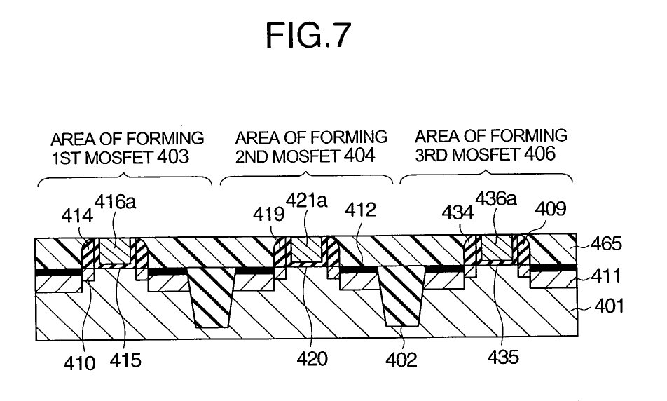

In the following, a preferred Embodiment 2 of the present invention will be described. FIG. 7 is across-sectional diagram of a MOSFETs structure in accordance with Embodiment 2. In Embodiment 2, components corresponding to those described in the above Embodiment 1 are assigned similar reference numbers in which the highest digit is replaced by 4 and their detailed explanation is not repeated.

As is shown in FIG. 7, in the MOSFETs structure of Embodiment 2, a device isolation layer 402 is created on the surface of a p-type Si substrate 401 to form the boundaries between two adjacent areas among the areas of forming first, second, and third MOSFETs 403, 404, 406. An insulation layer 465 covers the Si substrate 401 and a first trench 414 in which a gate electrode will be formed is created in the area of forming the first MOSFET 403. Inside the first trench 414, a first gate insulation layer 415 and a first gate electrode 416a are formed. The first gate insulation layer 415 is made of material such as SiO₂, SiON, ZrO₂, HfO₂, Ta₂O₅, Al₂O₃, TiO₂, etc. The conductive layer that constitutes the first gate electrode 416a is formed, consisting of a single layer or a plurality of layers of AL, Mo, TaN, W, Ti, Ni, Co, V, Zr, and SiGe.

Similarly, a second trench 419 in which a gate electrode will be formed is created in the area of forming the second MOSFET 404. Inside the second trench 419, a second gate insulation layer 420 and a second gate electrode 421a are formed. Also, a third trench 434 in which a gate electrode will be formed is created in the area of forming the third MOSFET 406. Inside the third trench 434, a third gate insulation layer 435 and a third gate electrode 436a are formed. The first to third gate insulation layers, 415, 420, 435 are formed so that at least two or all of them have different thicknesses or are made of different kinds of materials. Also, the first to third gate electrodes 416a, 421a, 436a are formed so that the conductive layers of at least two or all of them are made of different kinds of materials. Side walls 409 are formed on the sides of the first to third gate electrodes 416a, 421a, 436a. Moreover, extension regions 410 are created from under the side walls 409 to each device isolation region 402 on the surface of the Si substrate 401. Also, diffusion layer regions 411 are created from the ends of the side walls 409 to each device isolation region 402 on the surface of the Si substrate 401. Impurities are implanted into the extension regions 410 and the diffusion layer regions 411 and the extension regions 410 are shallower than the diffusion layer regions 411 in junction depth. The extension regions 410 and diffusion layer regions 411 form source/drain regions on the either sides of the first to third gate electrodes 416a, 421a, 436a. Some of the diffusion layer regions 411 are overlaid with silicides 412 that have been formed through the reaction of the Si substrate 401 with a metal having a high melting point such as Ti, Co, or Ni.

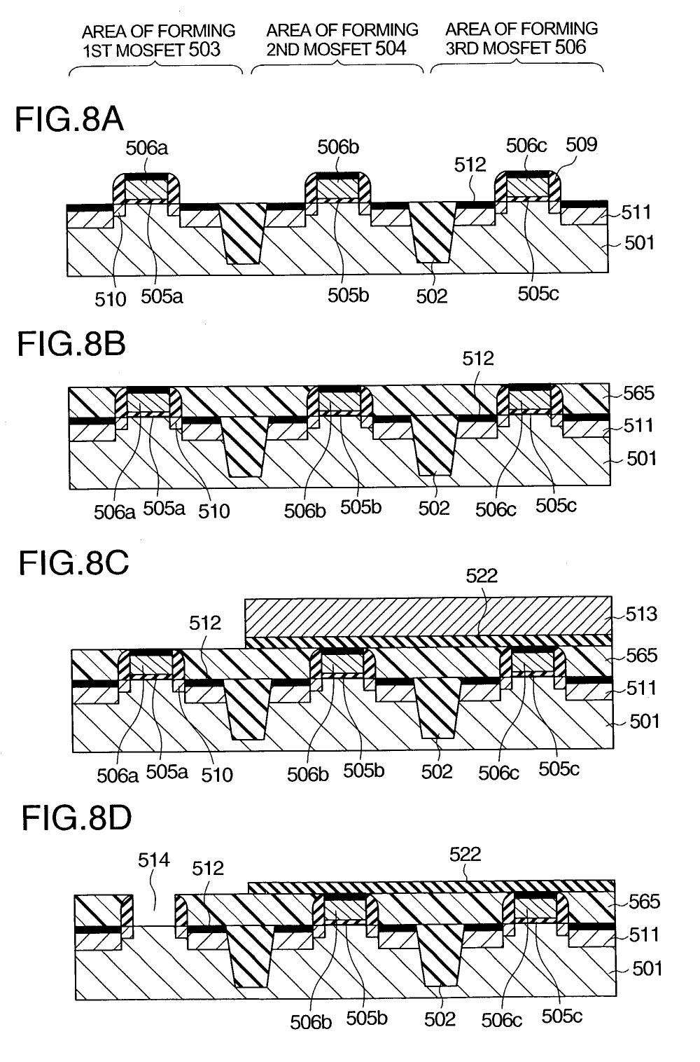

In the following, a method for fabricating MOSFETs in accordance with Embodiment 2 will be described. In Embodiment 2, in addition to different types of MOSFETs which can be co-fabricated through the method of Embodiment 1, another type of MOSFET with a different supply voltage, threshold, or “off” leakage current can be co-fabricated with the foregoing MOSFETs. FIGS. 8A through 8D, FIGS. 9A through 9D, FIGS. 10A through 10C, and FIGS. 11A through 11C are cross-sectional diagrams illustrating the sequential steps of fabricating MOSFETs by the method in accordance with Embodiment 2.

First, as is shown in FIG. 8A, a device isolation layer 502 is formed on the surface of a p-type Si substrate 501 to form the boundaries between two adjacent areas among the area of forming a first MOSFET 503, the area of forming a second MOSFET 504, and the area of forming a third MOSFET 506. In this case, the device isolation layer 502 is formed by STI, made of a plasma oxide film or the like. Then, well implantation is performed in the areas of forming the first to third MOSFETs 503, 504, 506.

Next, after a gate insulation layer that is approximately 3 nm thick and a polycrystalline Si layer that is approximately 150 nm thick are grown, the gate insulation layer and the polycrystalline Si layer are patterned. The gate insulation layer may be made of material such as SiO₂, SiON, ZrO₂, HfO₂, Ta₂O₅, Al₂O₃, TiO₂, etc. By patterning the above layers, a first dummy gate insulation layer 505a and a first dummy gate electrode 506a are formed in the area of forming the first MOSFET 503, a second dummy gate insulation layer 505b and a second dummy gate electrode 506b are formed in the area of forming the second MOSFET 504, and a third dummy gate insulation layer 505c and a third dummy gate electrode 506c are formed in the area of forming the third MOSFET 506.

Next, using the first to third dummy gate electrodes 506a, 506b, 506c as masks, impurities are implanted into the Si substrate 501. If the MOSFET to be formed is an NMOS, n-type impurities such as As must be implanted; if it is a PMOS, p-type impurities such as B must be implanted. Ion implantation of impurities is performed with energy of about 5 keV at an angle of 30 degrees obliquely to the Si substrate 501. If both NMOS and PMOS types are formed on the Si substrate 501, first, mask the area(s) of forming the NMOS with resist and implant B into only the PMOS area(s). Then, mask the area(s) of forming the PMOS with resist and implant As into only the NMOS area(s). The order in which these impurities are implanted may be reversed. In consequence, extension regions 510 are formed. Thereafter, pocket implantation may be performed, if necessary, to prevent punch-through.

Next, after an insulation layer approximately 700 nm thick is deposited over the entire area over the Si substrate 501, the insulation layer is anisotropically etched to form side walls 509. Insulation layers that form the side walls 509 are formed by depositing a single layer or a plurality of layers of an insulating material such as SiO₂ or Si₃N₄.

Then, using the first to third dummy gate electrodes 506a, 506b, 506c and the side walls 509 as masks, impurities are implanted into the Si substrate 501. If an NMOS is formed, implant n-type impurities such as As with energy of about 3 keV. If a PMOS is formed, implant p-type impurities such as B with energy of about 3 keV. Ion implantation of impurities is performed at a right angle to the Si substrate 501. If both NMOS and PMOS types are formed on the Si substrate 501, alternately select the area(s) to be ion implanted with impurities and mask the deselected area(s) with resist as is the case when forming the extension regions 510. Thereafter, annealing is performed to form diffusion layer regions 511 that behave as source or drain regions. Then, a metal having a high melting point such as Ti, Co, or Ni is deposited over the entire area over the Si substrate 501 to make an approximately 20 nm thick metal layer and a heating process is applied, thereby forming silicides 512 on the diffusion layer regions 511 and on the first to third dummy gate electrodes 506a, 506b, 506c.

Next, as is shown in FIG. 8B, after an interlayer dielectric layer 565, approximately 800 nm thick, made of SiO², is deposited over the entire area over the Si substrate 501 through the CVD process, the interlayer dielectric layer is planarized and removed through the CMP process until the top surfaces of the first to third dummy gate electrodes 506a, 506b, 506c are exposed, thereby forming the interlayer dielectric layer 565.

Next, as is shown in FIG. 8C, a first insulation layer 522, approximately 20 nm thick, made of a nitride film or the like, is deposited over the entire area over the Si substrate 501 through the CVD process. Then, a resist 513 is patterned to cover the areas of forming the second and third MOSFETs 504, 506 and, using the resist 513 as a mask, the first insulation layer 522 is wet etched with phosphoric acid or the like to expose the top surface of the first dummy gate electrode 506a.

Next, as is shown in FIG. 8D, after the resist 513 is removed, wet etching is performed, using an alkaline solution such as KOH, and thereby, the first dummy gate electrode 506a is removed. Then, the first dummy gate insulation layer 505a is removed, using hydrofluoric acid or the like, and, inconsequence, a first trench 514 is formed in which a gate electrode will be formed.

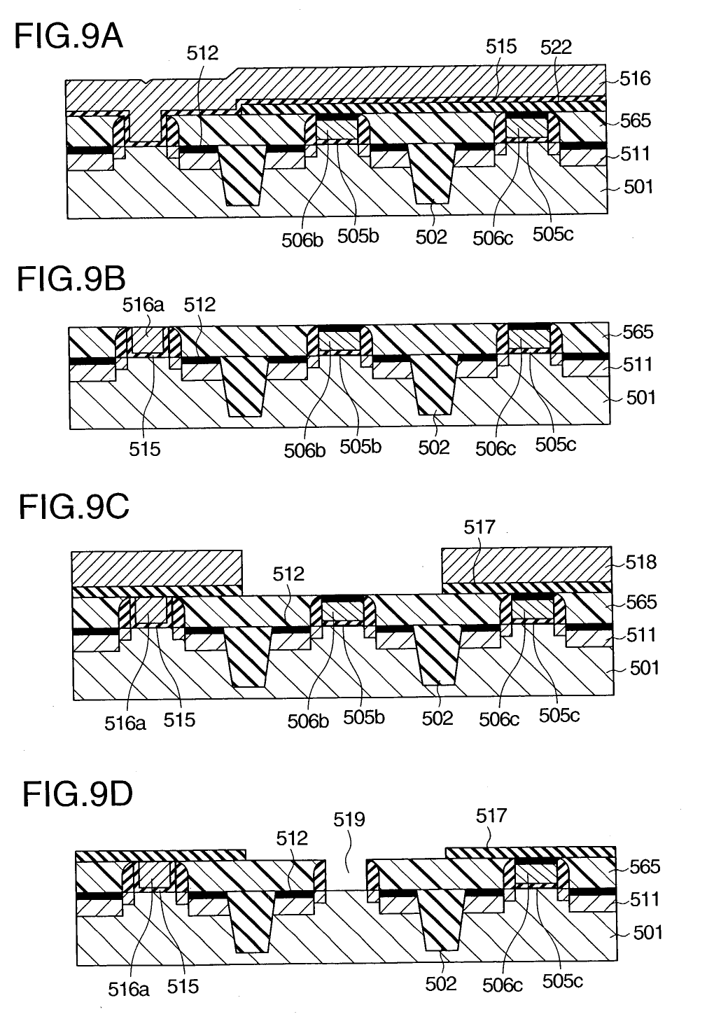

Next, as is shown in FIG. 9A, a first gate insulation layer 515 approximately 3 nm thick is formed inside the first trench 514. Material such as ZrO₂, HfO₂, Ta₂O₅, Al₂O₃, or TiO₂ is deposited through the CVD process to form the first gate insulation layer 515. During this deposition process, the material is deposited not only inside the first trench 514, but also on the interlayer dielectric layer 565 and the first insulation layer 522. Alternatively, when SiO₂, SiON, or the like is grown through a thermal oxidation process, the first gate insulation layer 515 is formed only on the bottom of the first trench 514. Thereafter, a first conductive layer 516 is deposited over the entire area through the sputter or CVD process. The first conductive layer 516 is formed, consisting of a single layer or a plurality of layers of AL, Mo, TaN, W, Ti, Ni, Co, V, Zr, and SiGe.

Next, as is shown in FIG. 9B, the first conductive layer 516 and the first insulation layer 522 over the interlayer dielectric layer 565 are removed through the CMP process, a first gate electrode 516a is formed, and the top surfaces of the second and third dummy gate electrodes 506b, 506c are exposed.

Next, as is shown in FIG. 9C, a second insulation layer 517, approximately 20 nm thick, made of a nitride film or the like, is deposited over the entire area over the Si substrate 501 through the CVD method. Then, a resist 518 is patterned to cover the areas of forming the first and third MOSFETs 503, 506 and, using the resist 518 as a mask, the second insulation layer 517 is wet etched with phosphoric acid or the like to expose the top surface of the second dummy gate electrode 506b.

Next, as is shown in FIG. 9D, after the resist 518 is removed, wet etching is performed, using an alkaline solution such as KOH, and thereby, the second dummy gate electrode 506b is removed. Then, the second dummy gate insulation layer 505b is removed, using hydrofluoric acid or the like, and, inconsequence, a second trench 519 is formed in which a second gate electrode will be formed.

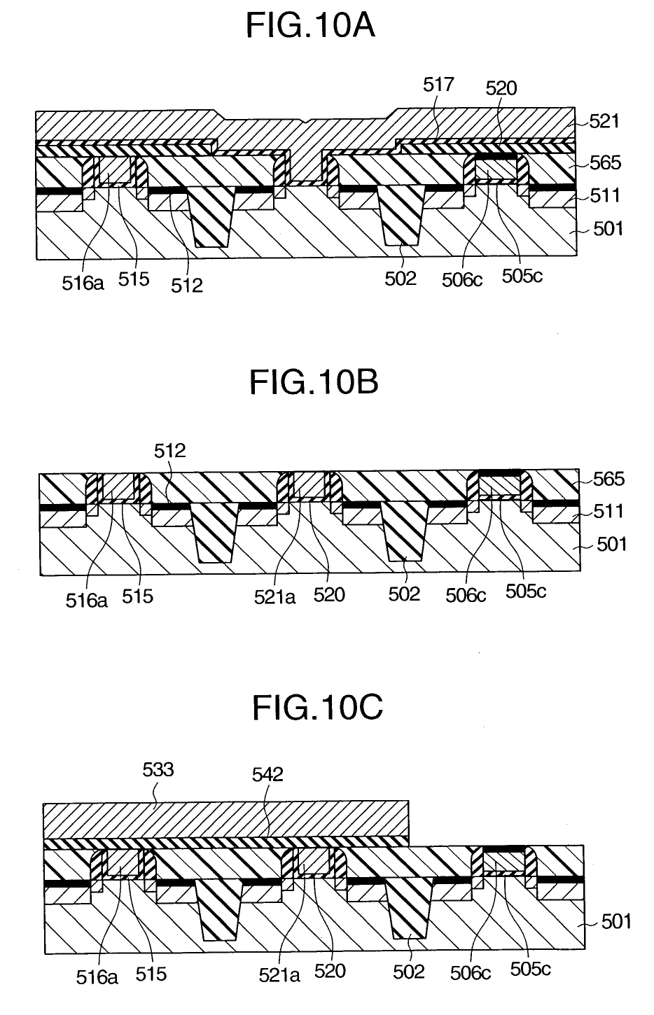

Next, as is shown in FIG. 10A, a second gate insulation layer 520 is formed inside the second trench 519. Although the second gate insulation layer 520 is formed in the same way as for the first gate insulation layer 515, its material and thickness may be different from or the same as those of the first gate insulation layer. Material and thickness optimum for the MOSFET to be formed should be selected. In this case, the second gate insulation layer, for example, approximately 2 nm thick, is formed. Thereafter, a second conductive layer 521 is deposited over the entire area through the sputter or CVD process. Although the second conductive layer 521 is formed in the same way as for the first conductive layer 516, its material may be the same as or different from that of the first conductive layer. The material can be changed to the optimum for the MOSFET to be formed.

Next, as is shown in FIG. 10B, the second conductive layer 521 and the second insulation layer 517 over the interlayer dielectric layer 565 are removed through the CMP process, a second gate electrode 521a is formed, and the top surfaces of the first gate electrode 516a and the third dummy gate electrode 506c are exposed.

Next, as is shown in FIG. 10C, a third insulation layer 542, approximately 20 nm thick, made of a nitride film or the like, is deposited over the entire area over the Si substrate 501 through the CVD process. Then, a resist 533 is patterned to cover the areas of forming the first and second MOSFETs 503, 504 and, using the resist 533 as a mask, the third insulation layer 542 is wet etched with phosphoric acid or the like to expose the top surface of the third dummy gate electrode 506c.

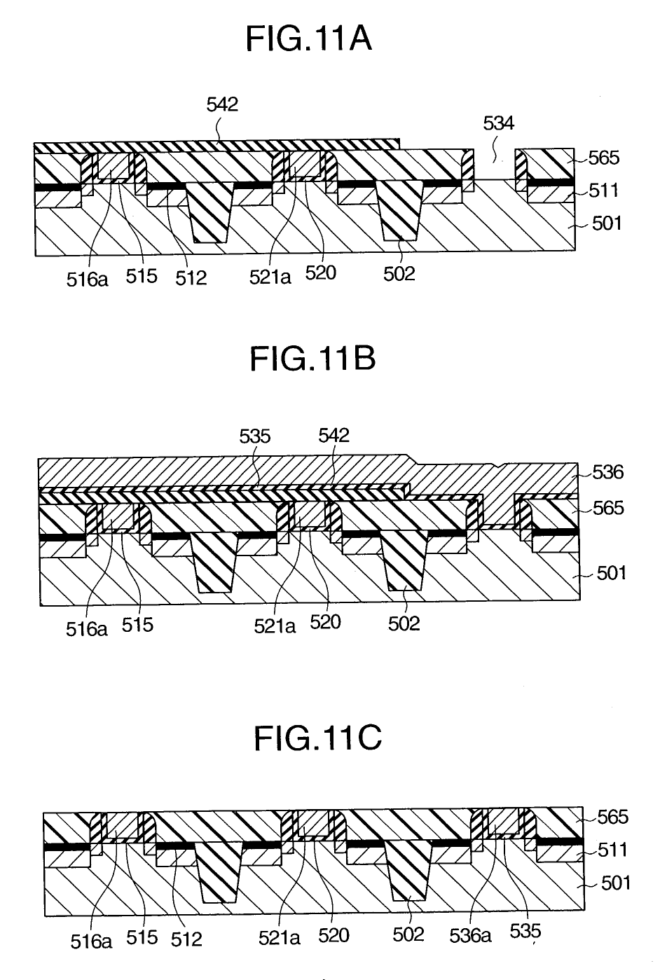

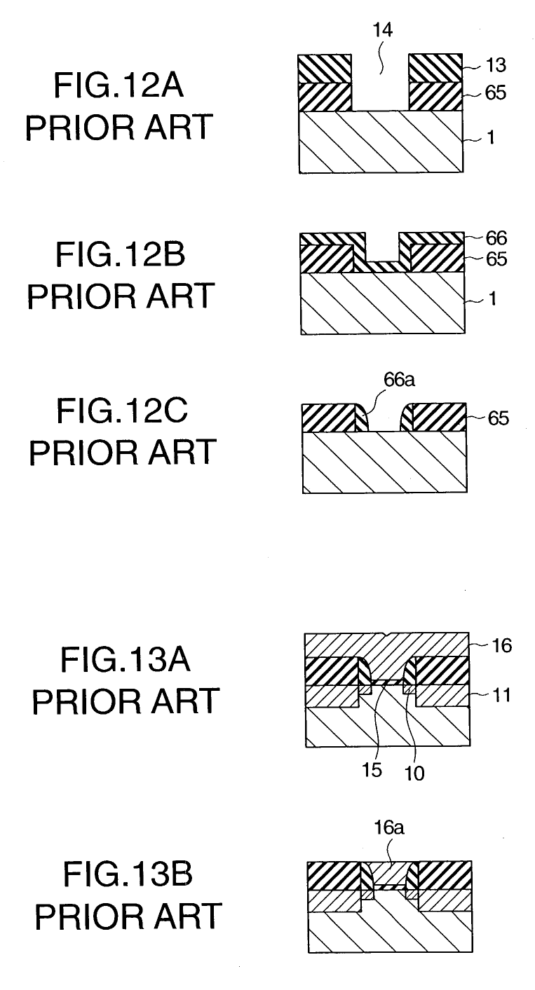

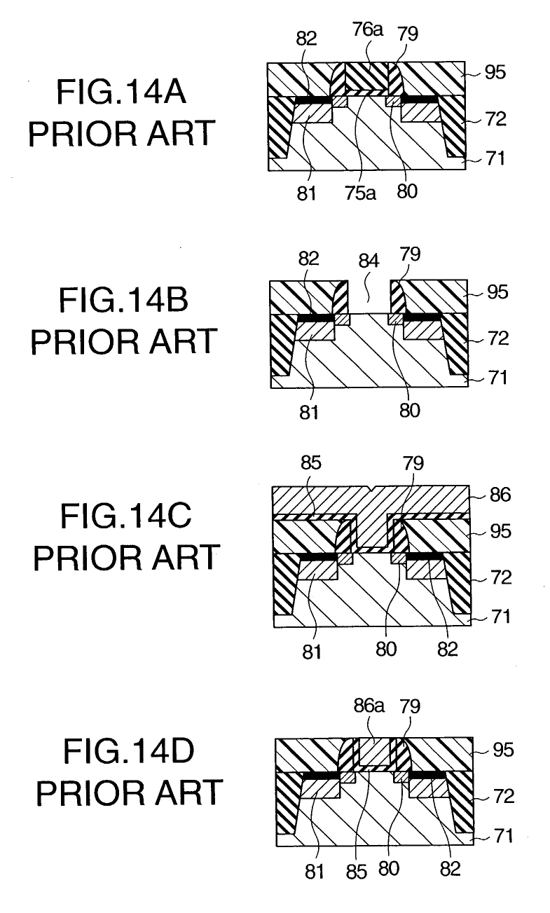

Next, as is shown in FIG. 11A, after the resist 533 is removed, wet etching is performed, using an alkaline solution such as KOH, and thereby, the third dummy gate electrode 506c is removed. Then, the third dummy gate insulation layer 505c is removed, using hydrofluoric acid or the like, and, in consequence, a third trench 534 is formed in which a third gate electrode will be formed.

Next, as is shown in FIG. 11B, a third gate insulation layer 535 is formed inside the third trench 534. Although the third gate insulation layer 535 is formed in the same way as for the first and second gate insulation layers 515, 520, its material and thickness may be different from or the same as those of the first and second gate insulation layers. Material and thickness optimum for the MOSFET to be formed should be selected. In this case, the third gate insulation layer, for example, approximately 1.5 nm thick, is formed. Thereafter, a third conductive layer 536 is deposited over the entire area through the sputter or CVD process. Although the third conductive layer 536 is formed in the same way as for the first and second conductive layers 516, 521, its material may be the same as or different from that of the first and second conductive layers. The material can be changed to the optimum for the MOSFET to be formed.

Next, as is shown in FIG. 11C, the third conductive layer 536 and the third insulation layer 542 over the interlayer dielectric layer 565 are removed through the CMP process, a third gate electrode 536a is formed, and the top surfaces of the first gate electrode 516a and the second gate electrode 521a are exposed. In the manner described above, in the areas of forming the first to third MOSFETs 503, 504, 506, MOSFETs can be formed, at least two or all of which differ in gate electrode material or gate insulation layer material and thickness.

Although the invention has been described with reference to specific embodiments, this description is not meant to be construed in a limiting sense. Various modifications of the disclosed embodiments will become apparent to persons skilled in the art upon reference to the description of the invention. It is therefore contemplated that the appended claims will cover any modifications or embodiments as fall within the true scope of the invention.

What is claimed is:

1. A method for fabricating semiconductor devices, comprising the steps of:
covering a semiconductor substrate on which there are an area of forming a first MOSFET and an area of forming a second MOSFET with an insulation layer only in the area of forming said second MOSFET;
forming a first trench in which a gate electrode will be formed in the area of forming said first MOSFET, using said insulation layer as a mask;
forming a first gate insulation layer on the bottom of said first trench;
forming a first gate electrode by filling said first trench with a conductive layer;
covering the area of forming said first MOSFET with an insulation layer;
forming a second trench in which a gate electrode will be formed in the area of forming said second MOSFET;
forming a second gate insulation layer whose thickness is different from the thickness of said first gate insulation layer on the bottom of said second trench; and
forming a second gate electrode by filling said second trench with a conductive layer.

2. A method for fabricating semiconductor devices, comprising the steps of:
covering a semiconductor substrate on which there are an area of forming a first MOSFET and an area of forming a second MOSFET with an insulation layer only in the area of forming said second MOSFET;
forming a first trench in which a gate electrode will be formed in the area of forming said first MOSFET, using said insulation layer as a mask;
forming a first gate insulation layer on the bottom of said first trench;
forming a first gate electrode by filling said first trench with a conductive layer;
covering the area of forming said first MOSFET with an insulation layer;
forming a second trench in which a gate electrode will be formed in the area of forming said second MOSFET;
forming a second gate insulation layer whose material is different from the material of said first gate insulation layer on the bottom of said second trench; and
forming a second gate electrode by filling said second trench with a conductive layer.

3. The method for fabricating semiconductor devices as recited in claim 2, wherein the thickness of said second gate insulation layer is different from the thickness of said first gate insulation layer.

4. A method for fabricating semiconductor devices, comprising the steps of:
covering a semiconductor substrate on which there are an area of forming a first MOSFET and an area of forming a second MOSFET with an insulation layer only in the area of forming said second MOSFET;
forming a first trench in which a gate electrode will be formed in the area of forming said first MOSFET;
forming a first gate insulation layer on the bottom of said first trench;
forming a first gate electrode by filling said first trench with a first conductive layer which consists of a single layer;
covering the area of forming said first MOSFET with an insulation layer;
forming a second trench in which a gate electrode will be formed in the area of forming said second MOSFET;
forming a second gate insulation layer on the bottom of said second trench; and
forming a second gate electrode by filling said second trench with a second conductive layer whose material is different from the material of said first conductive layer and which consists of a single layer.

5. The method for fabricating semiconductor devices as recited in claim 4, wherein said first conductive layer and said second conductive layer consist of at least two or more conductive layers.

6. The method for fabricating semiconductor devices as recited in claim 4, wherein said second gate insulation layer is made of material different from the material of said first gate insulation layer.

7. The method for fabricating semiconductor devices as recited in claim 4, wherein said second gate insulation layer is formed to have a different thickness from the thickness of said first gate insulation layer.

8. A method for fabricating semiconductor devices, comprising the steps of:
forming a first trench in which a gate electrode will be formed in an area of forming a first MOSFET on a semiconductor substrate;
forming a first gate insulation layer on the bottom of said first trench;
forming a first gate electrode by filling said first trench with a conductive layer;
forming an insulation layer over the entire area over said semiconductor substrate;
forming a resist pattern which covers the area of forming said first MOSFET, but not covering an area of forming a second MOSFET;
removing said insulation layer, using said resist pattern as a mask;
forming a second trench in which a gate electrode will be formed in the area of forming said second MOSFET;
forming a second gate insulation layer whose thickness is different from the thickness of said first gate insulation layer on the bottom of said second trench; and
forming a second gate electrode by filling said second trench with a conductive layer.

9. A method for fabricating semiconductor devices, comprising the steps of:
forming a first trench in which a gate electrode will be formed in an area of forming a first MOSFET on a semiconductor substrate;
forming a first gate insulation layer on the bottom of said first trench;
forming a first gate electrode by filling said first trench with a conductive layer;
forming an insulation layer over the entire area over said semiconductor substrate;
forming a resist pattern which covers the area of forming said first MOSFET, but not covering an area of forming a second MOSFET;
removing said insulation layer, using said resist pattern as a mask;
forming a second trench in which a gate electrode will be formed in the area of forming said second MOSFET;
forming a second gate insulation layer whose material is different from the material of said first gate insulation layer on the bottom of said second trench; and
forming a second gate electrode by filling said second trench with a conductive layer.

10. The method for fabricating semiconductor devices as recited in claim 9, wherein the thickness of said second gate insulation layer is different from the thickness of said first gate insulation layer.

11. A method for fabricating semiconductor devices, comprising the steps of:
forming a first trench in which a gate electrode will be formed in an area of forming a first MOSFET on a semiconductor substrate;
forming a first gate insulation layer on the bottom of said first trench;
forming a first gate electrode by filling said first trench with a first conductive layer which consists of a single layer;
forming an insulation layer over the entire area over said semiconductor substrate;
forming a resist pattern which covers the area of forming said first MOSFET, but not covering an area of forming a second MOSFET;
removing said insulation layer, using said resist pattern as a mask;
forming a second trench in which a gate electrode will be formed in the area of forming said second MOSFET;
forming a second gate insulation layer on the bottom of said second trench; and
forming a second gate electrode by filling said second trench with a second conductive layer whose material is different from the material of said first conductive layer and which consists of a single layer.

12. The method for fabricating semiconductor devices as recited in claim 11, wherein said first conductive layer and said second conductive layer consist of at least two or more conductive layers.

13. The method for fabricating semiconductor devices as recited in claim 11, wherein said second gate insulation layer is made of material different from the material of said first gate insulation layer.

14. The method for fabricating semiconductor devices as recited in claim 11, wherein said second gate insulation layer is formed to have a different thickness from the thickness of said first gate insulation layer.
